(19) United States
(12) Patent Application Publication
(10) Pub. No.: US 2025/0239496 A1
(43) Pub. Date: Jul. 24, 2025

(54) INTEGRATED CIRCUIT PACKAGE

(71) Applicant: STMicroelectronics International N.V., Geneva (CH)

(72) Inventor: Younes BOUTALEB, Grenoble (FR)

(73) Assignee: STMicroelectronics International N.V., Geneva (CH)

(21) Appl. No.: 19/020,177

(22) Filed: Jan. 14, 2025

(30) Foreign Application Priority Data
Jan. 18, 2024 (FR) FR2400509

(51) Int. Cl. H01L 23/053; H01L 21/48; H01L 23/00; H01L 23/08; H01L 23/10; H01L 23/24; H01L 23/498; H01L 25/16; H10F 39/00; H10F 39/95; H10H 29/14; H10H 29/20; H10H 29/85; H10H 29/855

(52) U.S. Cl. CPC H01L 23/053; H01L 21/4803; H01L 23/08; H01L 23/10; H01L 23/24; H01L 24/26; H01L 24/32; H01L 24/48; H01L 24/73; H10F 39/804; H10F 39/8063; H10F 39/811; H10F 39/95; H10H 29/14; H10H 29/20; H10H 29/8506; H10H 29/855; H10H 29/857; H01L 23/49816; H01L 25/167; H01L 2224/26145; H01L 2224/32225; H01L 2224/48229; H01L 2224/48991; H01L 2224/48996; H01L 2224/73215; H01L 2924/1616

(57) ABSTRACT

An integrated circuit package includes a substrate having a first surface and a second surface. An electronic integrated circuit chip has a first surface and a second surface, with the second surface mounted on the first surface of the substrate. A preformed glass cover is assembled on the first surface of the substrate and arranged to contain the electronic integrated circuit chip.

### PRIORITY CLAIM

This application claims the priority benefit of French Application for Patent No. 2400509, filed on Jan. 18, 2024, the content of which is hereby incorporated by reference in its entirety to the maximum extent allowable by law.

### TECHNICAL FIELD

The present disclosure generally concerns electronic devices and, in particular, electronic devices comprising an electronic chip in an integrated circuit package.

The present disclosure particularly concerns optical packages in which the electronic chip comprises optical or optoelectronic components.

### BACKGROUND

Conventionally, a type of integrated circuit package comprises at least one electronic integrated circuit (IC) chip arranged on a surface of a support substrate and protected by a coating. The electronic chip may be topped with a glass, which may also have a protective function. The coating may be a resin, molded at least around the edges of the electronic chip and integral with the support substrate. The glass may be positioned above the electronic chip and assembled thereto by adhesive. The other surface of the support substrate may comprise electrical connection structures, for example balls, configured to be bonded to a printed circuit board (PCB). The coating generally enables not only to protect the electronic chip, but also to contribute to the robustness of the package.

There is a need in the art to overcome all or part of the disadvantages of known integrated circuit packages.

### SUMMARY

An embodiment provides an integrated circuit package comprising: a substrate having a first surface and a second surface; an electronic integrated circuit (IC) chip having a first surface and a second surface assembled to the first surface of the substrate; and a preformed glass assembled on the first surface of the substrate and arranged to contain the electronic chip.

According to an embodiment, a cavity is located between the substrate and the preformed glass.

According to an embodiment, the electronic chip is electrically coupled to the substrate by electrically-conductive connection wires positioned in the cavity.

According to an embodiment, the first surface of the substrate comprises first contact pads, the first surface of the chip comprises second contact pads, and the connection wires are coupled to, for example soldered to, said first and second contact pads.

According to an embodiment, the package comprises, in the cavity, a protective layer coating at least the connection wires and, for example, also the first and second contact pads and/or the edges of the electronic chip.

According to an embodiment, the preformed glass is assembled to the substrate in a sealed manner.

According to an embodiment, the preformed glass is assembled to the substrate by an adhesive.

According to an embodiment, the preformed glass comprises a first portion extending substantially parallel to, and above, the electronic chip and at least a second portion coupled to the first portion and assembled to the substrate, for example the preformed glass has a prism shape.

According to an embodiment, the preformed glass has the shape of a dome, for example a spherical or ovoid dome.

According to an embodiment, the package further comprises a retaining piece between the electronic chip and the preformed glass, for example the retaining piece is assembled on the first surface of the electronic chip and the preformed glass rests on the retaining piece.

According to an embodiment, the second surface of the substrate comprises connection balls, for example for intended to assemble the substrate to a printed circuit board.

According to an embodiment, the package further comprises at least one optical component integrated in the chip or assembled on the first surface of the electronic chip, the package being an optical package.

An embodiment provides an electronic device comprising an integrated circuit package such as described hereabove.

An embodiment provides a method of assembling an integrated circuit package comprising: the provision of a substrate having a first surface and a second surface; the assembly of an electronic chip, comprising a first surface and a second surface, on the substrate so that the second surface of the electronic chip is on the first surface of the substrate; and the assembly of a preformed glass on the first surface of the substrate, said preformed glass being arranged to contain the electronic chip.

According to an embodiment, the method further comprises, after the assembly of the electronic chip on the substrate and before the assembly of the preformed glass on the first surface of the substrate: the electrical coupling of the chip to the substrate by electrically-conductive connection wires.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A is a cross-section view schematically showing an example of an integrated circuit package;

FIG. 1B is a cross-section view schematically showing another example of an integrated circuit package;

FIG. 2A is a cross-section view showing an integrated circuit package;

FIG. 2B is a cross-section view showing an integrated circuit package;

FIG. 2C is a cross-section view showing an integrated circuit package; and

FIG. 2D is a cross-section view showing an integrated circuit package.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

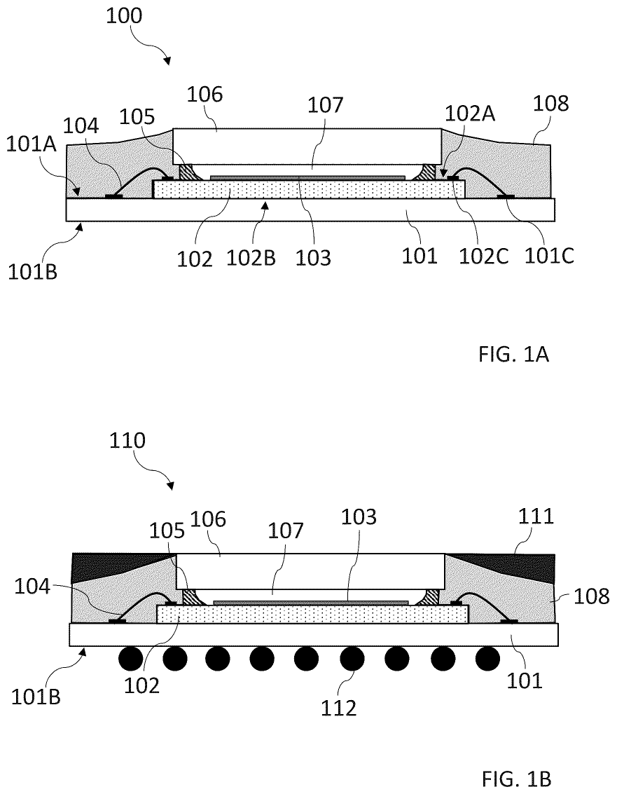

FIG. 1A is a cross-section view schematically showing an example of an integrated circuit package 100.

Package 100 is, for example, an optical package. It comprises a substrate 101 and at least one electronic integrated circuit (IC) chip 102 bonded to an upper surface 101A of substrate 101. Package 100 may further comprise a plurality of other electronic chips. However, for simplification, a single electronic chip 102 is shown.

Package 100 is in this example of the type using the “wire bonding” technology. In this example, electronic chip 102 has a lower surface 102B bonded to the upper surface 101A of substrate 101 by an adhesive layer (not shown), and an upper surface 102A. The upper surface 102A of electronic chip 102 comprises contact pads 102C electrically coupled to contact pads 101C on the upper surface 101A of substrate 101 by electrically-conductive connection wires 104 soldered to these contact pads. Connection wires 104 may be made of gold.

Substrate 101 may further comprise on its lower surface 101B connection balls (not shown in FIG. 1A, but visible in FIG. 1B), configured to be soldered, for example, to a printed circuit board (PCB).

An optical component 103 is assembled on the upper surface 102A of electronic chip 102. It may be an optical array, such as a lens array. One or a plurality of other optical and/or electronic components (not shown) may be formed inside and/or on top of electronic chip 102, for example one or a plurality of optical sensors and/or one or a plurality of light emitters.

Package 100 further comprises a glass 106 which is positioned above electronic chip 102 and which is assembled to electronic chip 102 by means of an adhesive layer 105. Glass 106 is preferably transparent to light at the wavelengths used during the operation of package 100. Glass 106 has a substantially planar shape, that is, glass 106 is not curved, or only slightly curved, whereby the need to have a layer of adhesive 105 of sufficient thickness to assemble it to electronic chip 102. The space between electronic chip 102 and optical component 103, glass 106, and adhesive layer 105 forms a cavity 107. Components positioned in cavity 107 can thus be protected by glass 106 and adhesive layer 105.

Integrated circuit package 100 further comprises a coating (such as an encapsulating material) 108. Coating 108 coats at least edges of electronic chip 102 and connection wires 104, as well as the different contact pads 101C, 102C. The material of coating 108 is preferably selected to give package 100 advantageous mechanical properties, enabling it to withstand the mechanical stress that may be exerted thereon. The material of coating 108 may be a resin, or an underfill material such as an epoxy-based material. The use of such an underfill 108 particularly contributes to the robustness of package 100.

FIG. 1B is a cross-section view schematically showing another example of an integrated circuit package 110.

The package 110 of FIG. 1B differs from the package 100 of FIG. 1A mainly in that it further comprises a layer 111 of a material different from the material of the coating, this layer being positioned on coating 108 on either side of glass 106. For example, layer 111 does not have a constant thickness. For example, layer 111 is sized to complete the level of coating 108 so as to be flush with the level of glass 106.

Preferably, the material of layer 111 is selected to increase the robustness of package 110, in particular to ensure the mechanical stability of glass 106 in package 110. The material of layer 111 is, for example, a plastic.

FIG. 1B further shows connection balls 112 assembled on the lower surface 101B of substrate 101, and intended to be soldered, for example, onto a printed circuit board (PCB).

Thus, the package of FIGS. 1A and 1B implements an assembly of a plurality of different materials, at least the material of coating 108, adhesive layer 105, and glass 106, as well as the material of layer 111 in the case of the package 110 of FIG. 1B. The use of these different materials may induce problems of stress within one or a plurality of materials, or between two different materials, risks of moisture infiltration into the package, risks of cracks within one or a plurality of materials, and/or risks of delamination between two different materials, for example due to different expansion coefficients. Moisture-induced delamination and cracking is a phenomenon known under the term “popcorn effect”. At high temperatures, the moisture present in the cavity of the package may vaporize and exert stress on the package from the inside, and this stress may cause a cracking of the package and/or a delamination between materials. This is a problem which influences the reliability of the integrated circuit package.

Embodiments of integrated circuit packages will be described hereafter. The described embodiments are non-limiting and various variants will occur to those skilled in the art based on the indications of the present disclosure. The embodiments provide integrated circuit packages enabling to meet the previously-described improvement needs, and to overcome all or part of the disadvantages of the previously-described integrated circuit packages.

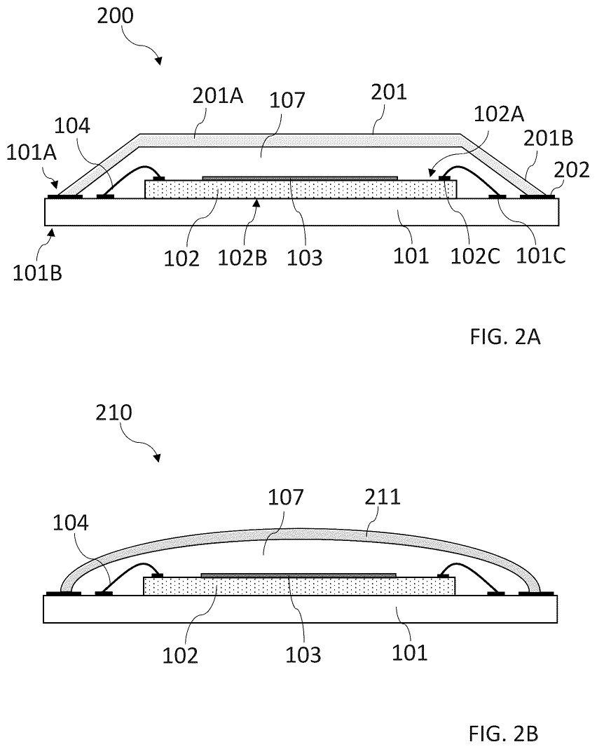

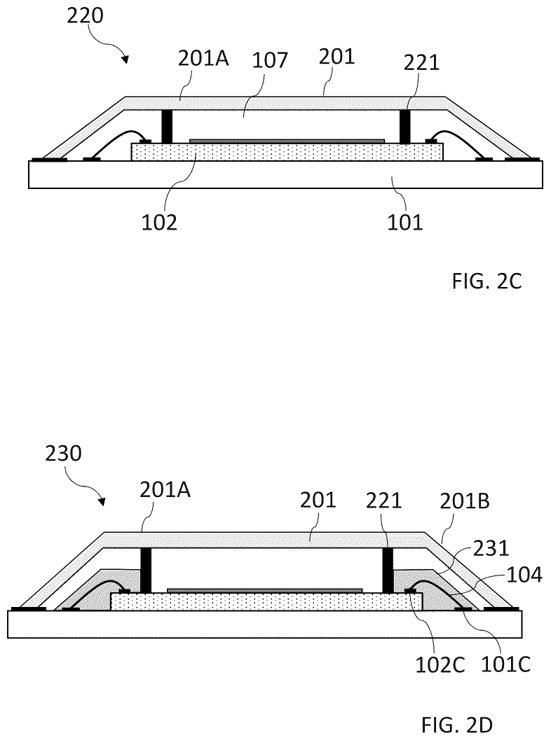

FIG. 2A is a cross-section view showing an integrated circuit package 200 according to an embodiment. Integrated circuit package 200 is, for example, an optical package.

Similarly to the packages 100 and 110 of FIGS. 1A and 1B, the package 200 of FIG. 2A comprises a substrate 101 and at least one electronic chip 102 bonded to an upper surface 101A of substrate 101. Although a single electronic chip is shown, package 200 may comprise a plurality of electronic chips.

Similarly to the packages 100 and 110 of FIGS. 1A and 1B, the package 200 of FIG. 2A is of the type using the wire bonding technology. Electronic chip 102 comprises a lower surface 102B bonded to the upper surface 101A of a substrate 101 by an adhesive layer (not shown), and an upper surface 102A. The upper surface 102A of electronic chip 102 comprises contact pads 102C electrically coupled to contact pads 101C on the upper surface 101A of substrate 101 by electrically-conductive connection wires 104 soldered to these contact pads. Connection wires 104 may be made of gold. An optical component 103 is assembled to the upper surface 102A of electronic chip 102. It may be an optical array, such as a lens array. One or a plurality of other optical and/or electronic components (not shown) may be formed inside and/or on top of electronic chip 102, for example one or a plurality of optical sensors and/or one or a plurality of light emitters.

Similarly to what is shown in FIG. 1B, substrate 101 may also comprise on its lower surface 101B connection balls intended to be soldered for example to a printed circuit board (PCB).

Elements similar to the elements of FIGS. 1A and 1B keep the same numerical references.

The package 200 of FIG. 2A differs from the packages 100 and 110 of FIGS. 1A and 1B mainly in that it comprises a preformed glass 201 cover which is assembled to substrate 101 and not to electronic chip 102, and which is arranged and sized to enclose, or contain, electronic chip 102.

A preformed glass can be defined as being a glass manufactured according to a shape which is defined so that the glass can contain the electronic chip, and possibly other electronic chips and/or electronic and/or optical components, and so that it can be assembled to the substrate, preferably by forming a cavity between the electronic chip and the substrate. The preformed glass may be manufactured by using a molding technique, for example a precision glass molding technique, such as a molding technique used to manufacture precision optical components made of glass, for example precision glass lenses. Such a glass molding technique particularly enables to manufacture in series a plurality of preformed glasses, while avoiding, for example, additional manufacturing costs.

Preformed glass 201 advantageously replaces the coating 108, the adhesive layer 105, and the glass 106 of FIGS. 1A and 1B, and even layer 111 in the example of FIG. 1B. Thus, the use of a preformed glass enables to avoid problems of stress within, or between, the different materials, risks of moisture infiltration into the housing, the risks of cracking and the risks of delamination mentioned hereabove in relation with FIGS. 1A and 1B. Preformed glass 201 particularly enables to prevent the popcorn effect, and thus to improve the reliability of the integrated circuit package.

Further, preformed glass 201 is assembled to substrate 101, and not to electronic chip 102, conversely to the glass 107 of the packages of FIGS. 1A and 1B, in particular because preformed glass 201 may have a shape enabling it to assemble to substrate 101. Thus, it is possible to decrease the size of electronic chip 102, since it is not necessary to provide a surface portion on this electronic chip to assemble the preformed glass thereto.

Preformed glass 201 is preferably transparent to light at the wavelengths used during the operation of housing 200.

A space, or cavity 107, is formed between electronic chip 102 with optical component 103 and preformed glass 201. The components positioned in cavity 107 can thus be protected by preformed glass 201.

Preferably, preformed glass 201 is assembled to substrate 101 in a sealed manner, for example to avoid moisture infiltrations into package 200. In the shown example, the preformed glass 201 is assembled to substrate 101 in a sealed manner by means of an adhesive 202, for example an epoxy adhesive.

Adhesive 202 can absorb expansion variations between substrate 101 and preformed glass 201, enabling to make package 200 stable and robust, particularly by further decreasing the risk of delamination.

Preformed glass 201 is not entirely planar, that is, it does not extend along a single plane.

In the embodiment shown in FIG. 2A, preformed glass 201 has the shape of a trapezoidal prism without the large base (for example, the base is hollow), that is, it comprises a first planar portion 201A (small base) extending substantially in a horizontal plane, parallel to and above electronic chip 102, and second planar portions 201B oblique with respect to the first portion, coupled to the edges of first portion 201A and assembled to substrate 101.

Other shapes can also be envisaged. For example, the preformed glass may have a parallelepiped shape (without one of the bases), or any other shape comprising a first substantially planar portion parallel to the electronic chip, and oblique second portions coupled to the edges of the first portion and assembled to the substrate. It is possible for the first portion not to be planar or entirely planar. Thus, the first portion may be curved, for example domed towards the outside of the package. It is possible for the second portions not to be planar or entirely planar, for example to have a domed shape. Instead of second portions, it may be a single second continuous portion coupling the first portion and the substrate.

FIG. 2B is a cross-section view showing an integrated circuit package 210, for example an optical package, according to another embodiment, in which preformed glass 211 does not have a parallelepiped shape, but has an ovoid dome shape. As a variant, the preformed glass may have the shape of a non-ovoidal dome, for example of a spherical dome, or any other adapted dome shape.

The other elements of integrated circuit package 210 in FIG. 2B may be similar to the elements of the package 200 of FIG. 2A, and keep the same numerical references.

FIG. 2C is a cross-section view showing an integrated circuit package 220, for example an optical package, according to another embodiment, which differs from the package 200 of FIG. 2A mainly in that it further comprises a retaining piece 221 between electronic chip 102 and preformed glass 201, for example between electronic chip 102 and the first portion 201A of the preformed glass. Retaining piece 221 may be assembled to electronic chip 102, preferably on the upper surface 102A of the electronic chip, and preformed glass 201 may rest on this retaining piece.

Retaining piece 221 may be crown-shaped or ring-shaped in top view, or have any other adapted shape. As a variant, the retaining piece may be made up of a plurality of elements, for example a plurality of holding rods.

Retaining piece 221 may be used to reinforce the hold of preformed glass 201 above electronic chip 102, for example to prevent a subsidence of preformed glass 201 towards the cavity 107 and/or to maintain a substantially constant distance between the first portion 201A of preformed glass 201 and electronic chip 102. Retaining piece 221 may contribute to reinforcing the robustness of package 220.

Retaining piece 221 may, for example, be made of a plastic, of an adhesive, or of an epoxy-based material.

Retaining piece 221 is shown in FIG. 2C with a trapezoidal prism-shaped preformed glass 201, but may apply to any other preformed glass shape, in particular the dome shape of FIG. 2B.

The other elements of integrated circuit package 220 in FIG. 2C may be similar to the elements of the package 200 of FIG. 2A, and keep the same numerical references.

FIG. 2D is a cross-section view showing an integrated circuit package 230, for example an optical package, according to another embodiment, which differs from the package 220 of FIG. 2C mainly in that it further comprises a coating 231 (protective layer), which covers at least edges of electronic chip 102, connection wires 104, as well as contact pads 101C, 102C. Coating 231 is contained in cavity 107. The material of coating 231 may be a resin, or an underfill material such as an epoxy-based material. The use of this coating 231 contributes to protecting connection wires 104 and thus the electrical connection between electronic chip 102 and substrate 101, as well as the edges of electronic chip 102. Preferably, coating 231 does not come onto optical component 103.

The package 230 of FIG. 2D further comprises retaining piece 221, coating 231 being located between the second portions 201B of preformed glass 201 and retaining piece 221, for example stopping against retaining piece 221 which functions as a dam structure, surrounding the optical element 103, for inhibiting or precluding spreading of the coating 231 over sensitive areas of the electronic chip 102 (for example, over a sensor element or optical component 103 of the chip).

The other elements of the integrated circuit package 230 of FIG. 2D may be similar to the elements of the package 200 of FIG. 2A, and keep the same numerical references.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An integrated circuit package, comprising:
a substrate having a first surface and a second surface;
an electronic integrated circuit (IC) chip having a first surface and a second surface, wherein the second surface is assembled on the first surface of the substrate; and
a preformed glass cover assembled on the first surface of the substrate and arranged to contain the electronic IC chip.

2. The package according to claim 1, wherein a cavity is located between the substrate and the preformed glass cover.

3. The package according to claim 2, wherein the electronic IC chip is electrically coupled to the substrate by electrically-conductive connection wires positioned in the cavity.

4. The package according to claim 3, wherein the first surface of the substrate comprises first contact pads, the first surface of the electronic IC chip comprises second contact pads, and the connection wires are coupled to, for example soldered to, said first and second contact pads.

5. The package according to claim 3, further comprising, in the cavity, a protective layer coating at least the connection wires, the first and second contact pads and edges of the electronic IC chip.

6. The package according to claim 5, further comprising, in the cavity, a dam structure at the first surface of the electronic IC chip and positioned surrounding an optical element of the electronic IC chip, the dam structure configured to inhibit spread of the protective layer onto the optical element.

7. The package according to claim 1, wherein the preformed glass cover is assembled to the substrate in a sealed manner.

8. The package according to claim 1, wherein the preformed glass cover is assembled to the substrate by an adhesive.

9. The package according to claim 1, wherein the preformed glass cover comprises a first portion extending substantially parallel to, and above, the electronic IC chip and at least a second portion coupled to the first portion and assembled to the substrate.

10. The package according to claim 9, wherein the preformed glass cover has a prism shape.

11. The package according to claim 1, wherein the preformed glass cover has the shape of a dome.

12. The package according to claim 11, wherein the dome is spherical.

13. The package according to claim 11, wherein the dome is ovoid.

14. The package according to claim 1, further comprising a retaining piece between the electronic IC chip and the preformed glass cover, wherein the retaining piece is assembled on the first surface of the electronic IC chip and the preformed glass cover rests on the retaining piece.

15. The package according to claim 1, wherein the second surface of the substrate comprises connection balls for assembling the substrate to a printed circuit board.

16. The package according to claim 1, further comprising at least one optical component integrated in the electronic IC chip, wherein the package is an optical package.

17. The package according to claim 1, further comprising at least one optical component assembled on the first surface of the electronic IC chip, wherein the package is an optical package.

18. An electronic device comprising the integrated circuit package according to claim 1.

19. A method of assembling an integrated circuit package, comprising:
providing a substrate having a first surface and a second surface;
assembling an electronic integrated circuit (IC) chip, comprising a first surface and a second surface, on the substrate so that the second surface of the electronic IC chip is on the first surface of the substrate; and
assembling a preformed glass cover on the first surface of the substrate, said preformed glass cover being arranged to contain the electronic IC chip.

20. The method according to claim 19, further comprising, after the assembly of the electronic IC chip on the substrate and before the assembly of the preformed glass on the first surface of the substrate:
electrically coupling of the electronic IC chip to the substrate by electrically-conductive connection wires.

21. The method according to claim 20, further comprising, after electrically coupling, coating at least the connection wires, the first and second contact pads and edges of the electronic IC chip with a protective layer.

22. The method according to claim 21, further comprising, before coating, forming a dam structure at the first surface of the electronic IC chip and positioned surrounding an optical element of the electronic IC chip, the dam structure configured to inhibit spread of the protective layer onto the optical element.
